(19) United States
(12) Patent Application Publication
(10) Pub. No.: US 2023/0387032 A1
(43) Pub. Date: Nov. 30, 2023

(54) SEMICONDUCTOR DEVICE AND MANUFACTURING METHOD THEREOF

(71) Applicant: nD-HI Technologies Lab,Inc., Taipei City (TW)

(72) Inventor: Ho-Ming TONG, Taipei City (TW)

(21) Appl. No.: 18/202,310

(22) Filed: May 26, 2023

Related U.S. Application Data
(60) Provisional application No. 63/346,333, filed on May 27, 2022.

(51) Int. Cl. H01L 23/538; H10B 80/00; H01L 25/065; H01L 25/18; H01L 23/31; H01L 23/367; H01L 23/552; H01L 21/48

(52) U.S. Cl. CPC H01L 23/5386; H10B 80/00; H01L 25/0655; H01L 25/0657; H01L 25/18; H01L 23/3128; H01L 23/367; H01L 23/5383; H01L 23/5389; H01L 23/552; H01L 21/4857

(57) ABSTRACT

A semiconductor device is provided. The semiconductor device includes a core, a first build-up structure and an input/output conductive structure. The core has a first surface and a second surface. The first build-up structure is formed on the first surface and/or the second surface and includes a plurality of first build-up conductive portions. The input/output conductive structure is formed above the first build-up structure and includes a plurality of input/output conductive portions. An input/output line width/line spacing (L/S) of the input/output conductive portions is different from a first L/S of the first build-up conductive portions.

This application claims the benefit of U.S. provisional application Ser. No. 63/346,333, filed May 27, 2022, the disclosures of which are incorporated by reference herein in its entirety.

### TECHNICAL FIELD

The disclosure relates in general to a semiconductor device and a manufacturing method thereof.

### BACKGROUND

The explosive growth of 5G and AI applications has led to exponential growth in data traffic at global data centers from 6.8 zettabytes (6.8×10²¹ bytes) for 2016 to 20 zettabytes for 2021, about 3× growth in 5 years. To cope with this unprecedented data growth which is accelerating even as we speak, high performance computing (HPC), data centers and artificial intelligence (AI) applications have been deploying state-of-the-art ICs (integrated circuits such as system-on-chips, SoCs) and state-of-the-art SiPs (system-in-a-packages).

Today, the best mainstream fine-line width/space (L/S) capabilities (which translate to fine-pitch capabilities) offered by substrate industry leaders using the ABF (Ajinomoto build-up film from Ajinomoto Fine-Techno Company of Japan) based build-up processes are around 6+ μm/6+ μm L/S or 8+ μm/9+ μm L/S depending on product complexities. Given these best-can-do mainstream L/S build-up capabilities, larger-than-ever laminate substrate sizes and higher-than-ever layer counts will inevitably give rise to lower substrate yields and higher substrate costs in laminate substrate processing which relies on large panels (e.g., 20″×24″) based on BT resin (bismaleimide triazine resin, which was developed by Mitsubishi Gas Company of Japan) and ABF resin. Even though the substrate industry and related equipment industries have been endeavoring to scale to ultrafine lines and spaces in panel-level substrate processing in order to reduce the substrate sizes and layer counts for a given application, it is still many years away for mainstream panel-level build-up substrate processes to scale to 2 μm/2 μm L/S and beyond with high yields, particularly for applications requiring the aforementioned unprecedented large substrate sizes and high layer counts.

As the silicon technology advances from 5 nm to 3 nm and beyond, processor chip power for data centers will continue to increase from up to 300 W/chip for CPUs and 700 W/chip for GPUs to 1000 W and beyond in the foreseeable future for data centers in order to process the exploding data traffic. For certain AI applications (for example, Cerebras's wafer-scale SoC), chip power has already reached an astounding 20 kW/chip. Regardless of the advanced SiP types used to package these advanced chips, this run-away chip power trend imposes severe thermal management, process and reliability challenges on today's state-of-the-art laminate substrates which are already maxing out on their capabilities to support future advanced ICs and advanced SiPs.

The BT and ABF resins used in making the advanced laminate substrates are known poor thermal conductors. Laminate substrates containing BT/glass fabrics at cores are also known to be poor thermal conductors. Their thermal conductivities range typically between 0.3 and 0.6 W/(m·K), far lower than that of silicon (148 W/(m·K)), or that of copper (386 W/(m·K)). It has become increasingly more important that advanced laminate substrates possess high thermal conductivities to help dissipate the unprecedented amount of heat from high-power processors built by advanced IC nodes.

To minimize the stresses exerted on the flip chip joints between the laminate substrate and the chip (e.g., the processor IC) or between the laminate substrate and the silicon interposer during chip operation, it is advisable that advanced laminate substrates possess a coefficient of thermal expansion (CTE) that more closely matches the CTE of silicon (˜3 ppm/° C.). The CTE of a laminate substrate is typically 16-18 ppm/° C. in the x-y (or in-plane) direction, and far higher in the z direction. The high CTEs of the laminate substrates has serious consequences particularly if it involves large chips and/or large silicon interposers which is often the case for future HPC, data center and high-end AI applications. The large CTE mismatch between the laminate substrate and the silicon can damage the solder joints as the laminate expands at a higher rate than the large silicon interposer or silicon chip. The repeated mismatch in expansion during chip operation and thermal cycling will create shear forces on the solder joints which will create stresses and can cause premature micro-cracking reliability failures over time. The problem tends to be exacerbated with increasing substrate sizes, layer counts, chip/interposer sizes and chip power. To mitigate this problem, it is therefore highly desirable to tailor the large, multi-layered advanced laminate substrates to achieve simultaneously ultrafine pitches that will scale with advanced ICs and advanced SiPs and also lower effective CTEs and higher effective thermal conductivities.

In advanced SiPs involving the connection of two or more chips to large, high-layer-count build-up laminate substrates, it is also advantageous to embed silicon interconnect substrates (which are fabricated using vintage silicon technologies) in the laminate substrate underneath the two chips where finer lines, spaces and bump pitches are required. A case in point is Intel's EMIB (Embedded Multi-Die Interconnect Bridge) which is embedded in the laminate substrate. Embedding of the silicon interconnect substrate which can be a passive component or an active component can help improve substrate yield as coarser lines and spaces can be applied to laminate substrate areas beyond the areas in close proximity to the silicon interconnects. For 2.5D IC packaging, both silicon interposers and advanced laminate substrates supporting silicon interconnects (either embedded in or mounted on the laminate substrates) can be considered as the chip bearing substrates. When 2.5D silicon interposers are used, they are typically mounted on advanced laminate substrates.

In addition to embedding “passive silicon interconnect bridges” in advanced laminate substrates, it is also the industry trend for HPC, data center, AI and other high-end applications to move “active” switching DC-DC voltage regulators (and accompanying inductors and/or capacitors) or the so-called integrated voltage regulators (IVRs; which integrate passives in the same package) from the printed circuit board to the processor package, i.e., to co-package the IVRs (or voltage regulators with inductors and decoupling capacitors) with the processor in the same package. This can lead to dramatic system efficiency improvement and as much as 30% to 50% system energy savings for data centers which accounts for 1% to 1.5% of global electricity consumption today. Switching regulators use a switching element which is typically one or two metal-oxide semiconductor field-effect transistors (MOSFETs) and an energy storage device (an inductor) to efficiently regulate an input voltage to a lower (“buck”) or higher (“boost”) output voltage. Up until recently, it has proven difficult to include the inductor inside the package due primarily to the sheer large sizes of inductors. Large and high-layer count substrates provide a relatively large untapped space to embed the IVRs or both the voltage regulators and the large inductors (and even decoupling capacitors) inside advanced SiPs.

### SUMMARY

In support of future advanced high-power processors built based on advanced IC nodes, future large, multi-layered advanced laminate substrates need to simultaneously enable (a) ultrafine L/Ss (or equivalently, pitches), (b) low effective CTEs and high effective thermal conductivities, (c) embedding of silicon interconnects and (d) embedding of voltage regulators which are grounded and Faraday shielded.

Example embodiment 1: a semiconductor device is provided. The semiconductor device includes a core, a first build-up structure and an input/output conductive structure. The core has a first surface and a second surface. The first build-up structure is formed on the first surface and/or the second surface and includes a plurality of first build-up conductive portions. The in input/output conductive structure is formed above the first build-up structure and includes a plurality of input/output conductive portions. Wherein an input/output line width/line spacing (L/S) of the input/output conductive portions is different from a first L/S of the first build-up conductive portions.

Example embodiment 2 based on Example embodiment 1: the first build-up structure is formed on the first surface of the core, and the semiconductor device further includes a second build-up structure. The second build-up structure is formed on the second surface of the core and includes a plurality of second build-up conductive portions. Wherein the input/output L/S or a second L/S of the second build-up conductive portions is different from the first L/S of the first build-up conductive portions.

Example embodiment 3 based on Example embodiment 1: the input/output L/S is smaller than the first L/S of the first build-up conductive portions.

Example embodiment 4 based on Example embodiment 1: the input/output conductive structure is a wafer-level or a panel-level fanout RDL (redistribution layers) structure or a wafer BEOL (back-end-of-line) structure.

Example embodiment 5 based on Example embodiment 1: the first build-up structure is located between the core and the input/output conductive structure.

Example embodiment 6 based on Example embodiment 1: the core includes a plurality of dielectric layers and a plurality of conductive vias. The dielectric layers are stacked on each other. The conductive vias pass through the dielectric layers and electrically connecting the first build-up structure and the second build-up structure.

Example embodiment 7 based on Example embodiment 1: the core includes a plurality of clad metal blocks or a clad metal plate with openings or cavities, an insulation layer enclosing the clad metal blocks, and a plurality of conductive vias passing through the insulation layer and electrically connecting the first build-up structure and the second build-up structure.

Example embodiment 8 based on Example embodiment 1: the semiconductor device further includes a semiconductor component disposed over and electrically connected to the input/output conductive structure which is grounded and Faraday shielded.

Example embodiment 9 based on Example embodiment 1: the minimal input/output L/S of the input/output conductive portions ranges between 1 micrometers (m) and 5 μm.

Example embodiment 10 based on Example embodiment 1: the semiconductor device further includes a semiconductor wafer and a cold plate. The semiconductor wafer has a first side and a second side opposite to the first side and includes a plurality of circuits formed on the second side. The cold plate is disposed on the first side. Wherein the core, the input/output conductive structure, the first build-up structure and the second build-up structure form a substrate for interconnection; and the substrate is disposed on the second side of the semiconductor wafer and is electrically connected to the circuits on the second side of the semiconductor wafer through the input/output conductive structure, and to a printed circuit board through the second build-up structure.

Example embodiment 11 based on Example embodiment 1: the semiconductor device further includes a heatsink with or without pistons housed in the heat spreader under the heatsink, a high-thermal-conductivity heat spreader and a silicon interconnect component supporting chips or chiplets. The silicon interconnect component is disposed between a first low-stress thermal conductor layer with a high-thermal conductivity material or a thermal interface material on both sides of the first low-stress thermal conductor under the heat spreader and the input/output conductive structure and being electrically connected to the input/output conductive structure. Wherein the entire semiconductor device is cooled via air cooling, direct-to-chip liquid cooling or liquid immersion cooling.

Example embodiment 12 based on Example embodiment 1: the semiconductor device further includes an interposer, at least one memory component and a processor. The interposer is disposed on the input/output conductive structure. At least one memory component is disposed on the interposer. The processor is disposed on the interposer. Wherein the at least one memory component and the processor are disposed side-by-side.

Example embodiment 13 based on Example embodiment 1: the semiconductor device further includes an interposer, at least one processor and a memory component. The interposer is disposed on the input/output conductive structure. At least one processor is disposed on the input/output conductive structure or the interposer. The memory component is mounted on top of each processor.

Example embodiment 14 based on Example embodiment 1: the semiconductor device further includes an electronic component, an encapsulation body and a conformal metal component and a compartment shield component over the encapsulation body. The electronic component is disposed on the input/output conductive structure for interconnection. The encapsulation body is formed on the input/output conductive structure and enclosing the electronic component. A conformal metal component and a compartment shield component over the encapsulation body, being electrically connected to a plurality of ground planes.

Example embodiment 15: the semiconductor device further includes a semiconductor chip embedded in in the core.

Example embodiment 16: a manufacturing method for a semiconductor device includes the following steps: forming a core, wherein the core has a first surface and a second surface; forming a first build-up structure formed on the first surface and/or the second surface, wherein the first build-up structure comprises a plurality of first build-up conductive portions; and forming an input/output conductive structure above the first build-up structure, wherein the input/output conductive structure comprises a plurality of input/output conductive portions. Wherein an input/output L/S of the input/out conductive structure is different from a first L/S of the first build-up conductive portions.

Example embodiment 17 based on Example embodiment 16: wherein the first build-up structure is formed on the first surface of the core, and the manufacturing method further includes: forming a second build-up structure on the second surface of the core, wherein the second build-up structure comprises a plurality of second build-up conductive portions. Wherein the input/output L/S is different from a second L/S of the second build-up conductive portions.

Example embodiment 18 based on Example embodiment 16: the input/output L/S is smaller than the first L/S of the first build-up conductive portions, and the minimal input/output L/S ranges between 1 μm and 5 μm.

Example embodiment 19 based on Example embodiment 16: the input/output conductive structure is formed by a wafer-level or a panel-level fanout RDL process or a wafer BEOL process.

Example embodiment 20 based on Example embodiment 16: the manufacturing method further includes: disposing a semiconductor component over and electrically connected to the input/output conductive structure of a substrate.

Example embodiment 21 based on Example embodiment 16: the manufacturing method further includes: disposing an electronic component on the input/output conductive structure of the substrate; forming an encapsulation body on the input/output conductive structure, wherein the encapsulation body encloses the electronic component; and forming a conformal metal component over the encapsulation body, wherein the conformal metal component which is electrically connected to a plurality of the ground planes of the substrate.

Example embodiment 22 based on Example embodiment 16: the manufacturing method further includes: embedding a semiconductor chip in the core.

The above and other aspects of the disclosure will become better understood with regard to the following detailed description of the preferred but non-limiting embodiment (s). The following description is made with reference to the accompanying drawings.

### BRIEF DESCRIPTION OF THE DRAWINGS

FIG. 1 is a schematic diagram of a semiconductor device 100 according to an embodiment of the present disclosure;

FIG. 2 is a schematic diagram of a semiconductor device 200 according to an embodiment of the present disclosure;

FIG. 3 is a schematic diagram of a semiconductor device 300 according to an embodiment of the present disclosure;

FIG. 4 is a schematic diagram of a semiconductor device 400 according to an embodiment of the present disclosure;

FIG. 5 is a schematic diagram of a semiconductor device 500 according to an embodiment of the present disclosure;

FIG. 6 is a schematic diagram of a semiconductor device 10 according to an embodiment of the present disclosure;

FIG. 7 is a schematic diagram of a semiconductor device 20 according to an embodiment of the present disclosure;

FIG. 8 is a schematic diagram of a semiconductor device 30 according to an embodiment of the present disclosure;

FIG. 9 is a schematic diagram of a semiconductor device 40 according to an embodiment of the present disclosure;

FIG. 10 is a schematic diagram of a semiconductor device 50 according to another embodiment of the present disclosure;

FIGS. 11A to 11H are schematic diagrams of manufacturing processes of the semiconductor device 200 of FIG. 2 according to another embodiment of the present disclosure; and

FIGS. 12A to 12H are schematic diagrams of manufacturing processes of the semiconductor device 400 of FIG. 4 according to another embodiment of the present disclosure.

In the following detailed description, for purposes of explanation, numerous specific details are set forth in order to provide a thorough understanding of the disclosed embodiments. It will be apparent, however, that one or more embodiments can be practiced without these specific details. In other instances, well-known structures and devices are schematically shown in order to simplify the drawing.

### DETAILED DESCRIPTION

The invention relates to the creation and manufacturing of large, high-layer-count, ultrafine L/S laminate substrates with or without a thermal expansion matched, high heat dissipating core, and with or without embedded active circuits (e.g., IVR) and/or passives (e.g., silicon interconnect, capacitor or inductor) in primarily the core layers of the substrate, which are way ahead of the present-day panel-level substrate industry capabilities for advanced SiP and other high-end flip chip packaging in support of HPC, data center, AI and other high-end applications.

As the advanced silicon technology is scaling from 5 nm to 2 nm in support of HPC, data center and AI applications, larger (≥13 cm×13 cm in width and width) and higher-layer count (≥26 layers) advanced, state-of-the-art organic laminate substrates is required for advanced processor ICs such as CPU (central processing unit), GPU (graphics processing unit), NPU (network processing unit) and FPGA (field-programmable gate array) even with the incorporation of 2.5D silicon interposers that take away some of the interconnect duties from the advanced laminate substrates. An extreme, advanced or state-of-the-art SiP such as a 2.5D IC package, wherein the silicon interposer with through silicon vias (TSVs) serves as the bridge between the chips or ICs and the laminate substrate, and the chips can comprise a logic die, a compute processor die such as a FPGA, a base die and several 3D multi-die HBM (high-bandwidth memory) DRAM stacks. The dies are interconnected to one another, or to the interposer through TSVs, redistribution layers (RDL) and/or copper pillar micro-bumps. In addition to 2.5D IC, advanced SiPs for processors also include 3D IC, fan-out, embedded SiPs, silicon photonics, chiplets-in-SiP and their combinations, all of which require advanced laminate substrates of different complexities that are covered under the scope of the present invention.

As advanced silicon technology scales from 5 nm to 3 nm and beyond, commensurate advanced packaging technologies also scale in line, space, and flip chip bump pitch. For 2.5D IC, 3D IC and fan-out SiP applications, mainstream L/S based on polyimide/Cu RDL has reached 2 μm/2 μm for 2.5D silicon interposers and fan-out redistribution layers based primarily on wafer-level (300 mm in diameter) processing. Simultaneously and as mentioned above, panel-level (20″×24″) substrate L/S capabilities based on, for instance, ABF/Cu has also advanced to 6+ μm/6+ μm or 10+ μm/10+ μm depending on substrate complexities. There exists a gap between mainstream wafer-level and mainstream panel-level substrate L/S capabilities for high yields. Wafer-level capabilities, however, are not limited at a L/S of 2 μm/2 μm when it comes to ultimate equipment capabilities. Take a mainstream 2.5D interposer, for instance, its interconnect layers can be created at a L/S of 2 μm/2 μm using vintage 65 nm IC back-end-of-the-line (BEOL) equipment which can easily be extended to lines and spaces beyond 1 μm/1 μm with a suitable dielectric. On the other hand, IC BEOL processes based on oxide/Cu or oxide/AI are already capable of an L/S of 1 μm/1 μm or smaller. To achieve ultrafine L/S, this invention has to do with combining wafer-level (e.g., fan-out), IC BEOL and panel-level substrate technologies and capabilities to create large, high-layer-count laminate substrates at an L/S of 2 μm/2 μm and beyond with an embedded low-CTE, high-thermal-conductivity material and embedded active components such as the IVRs and/or passive components when needed.

For HPC, data center, AI and other high-end applications, embedding passive silicon interconnects in substrate has grown in popularity in the recent past as mentioned earlier. For cell phone applications, embedding passives such as decoupling capacitors in laminate substrate for application processors has already become mainstream. “Passives” as such certainly can be embedded in the large, high-layer-count laminate substrates. Embedding “active” IVRs (or equivalently, voltage regulation circuits and accompanying passives) in the large, high-layer-count ultrafine L/S laminate substrate will be used as an example for demonstration purposes while taking heed to avoid the EMI effects through the formation of grounded Faraday cages inside the laminate substrate.

Power regulation solutions need many discrete components externally supporting the processor IC flip chip bonded to a substrate. In a solution, DC-DC power converters or regulators such as buck converters convert power from a high voltage to a low voltage for diverse microelectronics applications using power converter components, e.g., power management/control IC, power switches, large inductors and bulky capacitors mounted on a printed circuit board at a large distance away from the processor system-on-chip (SoC; top structure). This large distance consumes power from the power converter and creates significant power losses in the interconnect from the printed circuit board to the processor due to thermal conduction loss (=I²R where I is current and R is line resistance) and large AC impedance leading to dynamic changes in processor power consumption that requires power supply margins to ensure a high enough voltage for efficient operation of the processor. This also leads to bigger system footprint, more complex design, poor system power efficiency, inadequate response time, and lower accuracy than desired, thereby enlarging the energy footprint of digital world/economy. Attempts have been made to move power converter components, particularly, IVR, close to the processor package on the circuit board or co-package the IVR and passives as needed with the processor in the same package by mounting the IVR (and passives which can be large or bulky still) on the top side (processor side) or on both the top side (chip side) and bottom side (land side) of the package laminate substrate. Embedding the IVRs in the laminate substrate directly under the processor as disclosed herein goes one step further beyond mounting the IVRs on the laminate substrate in terms of reducing the resistance and AC impedance of the electrical interconnect and improving system operation energy efficiency. For energy hungry, data-intensive applications such as high performance computing, data centers, and AI, small-sized (on the order of 100 μm thick) IVRs and small sized passives are available. They provide performance, board space saving and cost benefits compared to the power management solutions.

This invention combines mainstream build-up substrate processes at 6+ μm/6+ μm in L/S for the fabrication of the bottom portion (i.e., BGA ball side) of the substrate consisting of build-up layers, and the core layers (as needed), and wafer-level processes such as wafer-level (e.g., fan-out) or IC BEOL processes for the fabrication of the top portion of the substrate (i.e., the chip side) which comprises top-side ultrafine L/S redistribution layers (RDL) to create large, high-layer-count, ultra-fine L/S substrates with top-side redistribution layers at ultra-fine lines and spaces, say, 2 μm/2 μm or beyond (i.e., finer), beyond the state-of-the-art substrate capabilities at 6+ μm/6+ μm. Because the curing of the polyimide dielectrics used in wafer-level (e.g., fan-out) processes often require high curing temperatures exceeding 400° C. which will cause the epoxies such as BT and ABF in the bottom substrate to out-gas and decompose, it is necessary to implement a low-curing-temperature polymer (e.g., a low-curing-temperature polyimide) in wafer-level (e.g., fan-out) processing, whose curing (say, up to around 250° C.) does not cause the epoxies to out-gas or degrade. The degradation temperature of BT resin is around 334° C. By the same token, the deposition temperature should not be too high (say, up to around 250° C.) when IC BEOL processes are deployed. Due to the maturity of glass carrier bonding and debonding processes in support of practically all highest-end advanced packaging technologies (such as fan-out, 2.5D IC, 3D memory stacking and 3D IC), this invention discloses a process which consists sequentially of the following key steps to build the large, high-layer-count, ultrafine-L/S (and ultra-thin compared to substrate processes) laminate substrates:

Bonding a partially built substrate structure (bottom substrate structure), which can be a BT/glass core with top and bottom ABF based build-up redistribution layers, or a coreless substrate with ABF based build-up layers (or a coreless substrate with embedded trace in ABF based build-up layers for applications requiring thin, ultrafine pitch laminate substrate), on a glass carrier using an adhesive/release layer commonly used in fan-out processing. When the bottom substrate structure is rigid enough with the core layers for instance, the glass carrier may not be needed.

Note 1: The bottom substrate structure can be built using the aforementioned standard substrate panel sizes (say, 20″×24″) for cost reduction. It preferably should, however, be cut into a few sub-panels of equal sizes (say, or 12″ wafers so as to be amenable to wafer-level or IC BEOL processing (typically 12″ in size).

Note 2: When a core layer is needed, the core used in the partial substrate structure above can be based on standard BT/glass core layers, or a low CTE and high thermal conductivity material such as a clad metal including Cu-Invar-Cu, diamond (which possesses the highest thermal conductivities of all known materials on Earth) or AlN. While AlN's and diamond's thermal properties (e.g., CTE and thermal conductivity) are constant and fixed, use of a clad metal such as Cu-Invar-Cu or Cu—Mo—Cu allows one to tailor its thermal properties by adjusting the individual layer thicknesses.

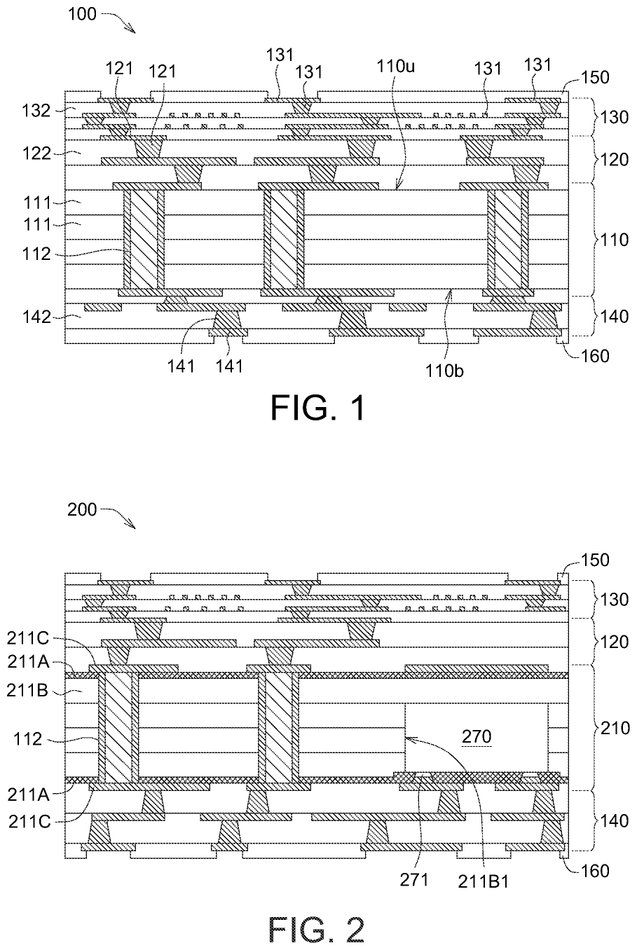

Referring to FIG. 1, FIG. 1 is a schematic diagram of a semiconductor device 100 according to an embodiment of the present disclosure. The semiconductor device 100 includes a core 110, a first build-up structure 120, an input/output conductive structure 130, a second build-up structure 140, a first solder mask 150 with pad openings and a second solder mask 160 with pad openings. The core 110 has a first surface 110u and a second surface 110b opposite to the first surface 110u. The first build-up structure 120 is formed on the first surface 110u and includes a plurality of first build-up conductive portions 121. The input/output conductive structure 130 is formed above the first build-up structure 120 and includes a plurality of input/output conductive portions 131. An input/output L/S of the input/output conductive portions 131 is different from a first L/S of the first build-up conductive portions 121.

As shown in FIG. 1, the core 110 is, for example, a laminate structure. Furthermore, the core 110 includes a plurality of dielectric layers 111 and a plurality of conductive vias 112. The dielectric layers 111 are stacked on each other. The conductive vias 112 pass through the dielectric layers 111 and electrically connecting the first build-up structure 120 with the second build-up structure 140. The dielectric layer 111 is formed of a material including, for example, BT/glass.

As shown in FIG. 1, in the present embodiment, the first build-up structure 120 is located between the core 110 and the input/output conductive structure 130. The first build-up structure 120 can be a single-layered structure or a multi-layered structure. For multi-layered structure, the first build-up structure 120 further includes a plurality of dielectric layers 122, wherein one of the first build-up conductive portions 121 can pass through one of the dielectric layers 122 for connecting another of the first build-up conductive portions 121 which is formed on a surface of the dielectric layer 122. The dielectric layer 122 is formed of a material including, for example, ABF.

As shown in FIG. 1, the input/output conductive structure 130 is an ultrafine L/S conductive structure. In an embodiment, the input/output conductive structure 130 is a wafer-level (or new panel-level fanout) RDL (redistribution layers) structure or a low-deposition-temperature wafer BEOL (back-end-of-line) structure. Accordingly, the input/output L/S is smaller than the first L/S of the first build-up structure. In an embodiment, the minimal input/output L/S can range between 1 micrometers (μm) and 5 μm, wherein 1 μm is based on wafer BEOL processes while 5 μm or smaller can be based on wafer processes. As a result, the semiconductor device 100 can provide a higher number of input/output (I/O) based on the input/output conductive structure 130 compared to the first build-up structure 120.

The input/output conductive structure 130 can be a single-layered structure or a multi-layered structure. For multi-layered structure, the input/output conductive structure 130 further includes a plurality of dielectric layers 132, wherein one of the input/output conductive portions 131 can pass through one of the dielectric layers 132 for connecting another of the input/output conductive portions 131 which is formed on a surface of the dielectric layer 132. The dielectric layer 132 is formed of a material including, for example, a low-curing-temperature, fine-L/S polyimide or a low-deposition-temperature IC BEOL oxide. The dielectric layer 132 is an ultrafine pitch dielectric layer.

As shown in FIG. 1, the second build-up structure 140 is formed on the second surface 110b of the core 110 and includes a plurality of second build-up conductive portions 141. The second build-up structure 140 can be a single-layered structure or a multi-layered structure. For multi-layered structure, the second build-up structure 140 further includes a plurality of dielectric layers 142, wherein one of the second build-up conductive portions 141 can pass through one of the dielectric layers 142 for connecting another of the second build-up conductive portions 141 which is formed on a surface of the dielectric layer 142. The dielectric layer 142 is formed of a material including, for example, BT or ABF.

As shown in FIG. 1, in an embodiment, the first build-up conductive portion 121 may be a trace, a conductive via, a conductive pad, etc., the input/output conductive portion 131 may be a trace, a conductive via, a conductive pad, a conductive pillar, etc., and the second build-up conductive portion 141 may be a trace, a conductive via, a conductive pad, a conductive pillar, etc.

As shown in FIG. 1, the first solder mask 150 covers the input/output conductive structure 130 and exposes at least one of the input/output conductive portions 131. The second solder mask 160 cover the second build-up structure 140 and exposes at least one of the second build-up conductive portions 141.

Referring to FIG. 2, FIG. 2 is a schematic diagram of a semiconductor device 200 according to another embodiment of the present disclosure. The semiconductor device 200 includes a core 210, the first build-up structure 120, the input/output conductive structure 130, the second build-up structure 140, the first solder mask 150, the second solder mask 160 and at least one electronic component (semiconductor component or semiconductor chip) 270.

The semiconductor device 200 includes the features similar to or the same as those of the semiconductor device 100, and at least one difference between them is that the semiconductor device 200 further includes the electronic component 270 and the core 210 of the semiconductor device 200 and the core 110 are different in structure.

As shown in FIG. 2, the core 210 includes a plurality of conductive via 112, a plurality of first dielectric layers 211A, a plurality of second dielectric layers 211B and a plurality of conductive portions 211C. The first dielectric layers 211A are disposed on two opposite sides of the embedded electronic component 270. At least one of the second dielectric layers 211B is pre-punched prepreg layers for receiving the electronic component 270. Furthermore, some second dielectric layers 211B have a recess 211B1 within which the electronic component 270 is disposed. In addition, the second dielectric layers 211B are pre-punched prepreg layers which can be formed of a material including, for example, BT/glass fabric. The conductive portions 211C are formed on two opposite sides of the first dielectric layers 211A. At least one conductive via 112 pass through the first dielectric layers 211A and the second dielectric layers 211B for electrically connecting the conductive portions 211C.

As shown in FIG. 2, in an embodiment, the electronic component 270 is, for example, an active component, a passive component or more than one of these components. For example, the electronic component 270 can be a grounded and Faraday shielded IVR, a voltage regulator component (for example, the first voltage regulator component), a voltage regulating circuit, or a sub-circuitry. In another example, the electronic component is a silicon interconnect substrate which can be a passive or an active component. The electronic component 270 includes at least one conductive contact 271 which is electrically connected, for example, to the second build-up structure 140, and electrically connected to the input/output conductive structure 130 through the core 210 and the first build-up structure 120.

As disclosed herein, a Faraday shield can be formed in the organic laminate substrate to surround or cage the embedded devices and components such as IVR, power regulator related components, other EMI sensitive circuitries and/or noisy circuitries in a cage-like pattern to minimize EMI impact and maximize processor performance and energy efficiency. One can move the IVRs from the top side and/or bottom side of the substrate to inside the substrate, right under the processor. Faraday shielding of the IVRs is achieved by surrounding the IVRs in a cage defined by metal layers on the top and bottom sides of the IVRs and through substrate vias connecting the top and bottom metal layers. The top and bottom layers can be part of the redistribution and build-up structures inside the substrate. They can appear on the top and bottom sides of the substrate or can be embedded inside the substrate. In an embodiment, the through-substrate-via spacing needed to ensure Faraday shield protection against substrate coupling is 1/10^{th} of a wavelength when silicon is used as the substrate. For typical RF applications in the 60 GHz to 100 GHz range, the wavelengths are around 2 mm and the required through-substrate-via spacing should be about 200 μm for protection against 60 GHz noise. For protection up to 200 GHz, the through-substrate-via spacing has to be decreased to around 50 μm. In practice, one can vary the through-substrate-via spacing to come up with the optimal spacing depending on the substrate type and frequency.

In making the ultrafine pitch substrates, one can also embed a low CTE and high heat dissipating and a high thermal conductivity core to control the effective CTE and effective thermal conductivity of the resultant ultrafine pitch advanced laminate substrate. Ceramics can be a candidate class of low-CTE and high thermal conductivity materials. Among ceramics, zirconia (˜10 ppm/° C.) and alumina (˜6.5 ppm/° C.) rank on the higher end, and cordierite (<3 ppm/° C.) and aluminum nitride, (AlN, ˜5 ppm/° C.) on the lower end in terms of thermal expansion. In contrast to most ceramics, AlN has one of the highest thermal conductivities of any ceramic, surpassed only by beryllium oxide. For mono-crystalline AlN, this value can reach as high as 285 W/(m·K) versus 150 W/(m·K) for silicon. For polycrystalline material, however, a value in the range of 70-210 W/(m·K) is more common. Besides AlN and clad metals, diamond can also be embedded in the substrates. Diamond has the highest thermal conductivity among all materials on Earth.

Diamond possesses “extreme” properties, notably, extreme thermal conductivity (˜24 W/cm·K) which is >5× that of copper, extremely high breakdown field (˜20 MV/cm), and extremely low thermal expansion coefficient (˜1 ppm/° C. at room temperature).

Although AlN and other low CTE and high thermal conducting materials can be considered as the core material that supports this invention, this invention specifically recommends using a lower cost clad metal such as copper-invar-copper (Cu-Invar-Cu) or copper-molybdenum-copper (Cu—Mo—Cu) as the core material, taking advantage of the thermal expansion matching that can be engineered or tailored between these clad metals, silicon and printed circuit board (PCB) supporting the substrate, and relative high thermal conductivities of clad metals. Invar is a Fe (iron) —Ni (nickel) alloy with a 36% nickel content that exhibits the lowest coefficient of thermal expansion (CTE) of all known metals and alloys, at for example, 1.2 ppm/° C. between 20 and 100° C., and its CTE stays low from the lowest temperatures up to approximately 230° C. By adjusting the thicknesses of copper, core metal (Invar or Mo) and copper, one can get the clad metal's CTE to be close to that of silicon (˜3 ppm/° C.), or between that of silicon and that of laminate substrate (16 ppm/° C.-18 ppm/° C.). An invar sheet having a thickness of between 0.5 mil and 5 mil, and a layer of electrodeposited copper on at least one side of a thickness between 1 μm and 50 μm has a CTE of 2.8 ppm/° C. to 6 ppm/° C. at a temperature between 0° F. and 200° F. In addition, one can adjust the thicknesses of the clad metal layers to achieve a high thermal conductivity, say 200 W/(m·K) to 300 W/(m·K) (versus 400 W/(m·K) for copper), which is much higher than that of silicon (150 W/(m·K)). In addition to the thermal advantages of clad metal cores, their relatively high young's modulus also make them more resilient to substrate and package warpage incurred during the operation of these high-performance, high-power systems. (Note: the Young's moduli of BT epoxy laminate and prepreg, Cu, Invar and Mo are, respectively, 4.7×10⁶ psi, 19×10⁶ psi, 21×10⁶ psi and 50×10⁶ psi.) Low thermal expansion mismatch between the silicon based die (or the interposer) and the substrate (with, say, the clad metal), better thermal conductivity of the substrate, and higher substrate modulus give rise to less warpage and induce less stresses at the flip chip joints, and thus better reliability during field operation.

The clad metal can be made thin using roll-to-roll processing. One side of the clad metal (or both sides of it) can be patterned and redistributed/re-routed using substrate-like processes as needed. The other side (often the chip side) can require finer lines and spaces in the redistribution layers. It can be processed using wafer-level (e.g., fan-out) processes (with the use of a glass carrier as needed) involving low-temperature dielectrics (e.g., a polyimide). Also, panel-level processing with length and width in excess of 500 mm based on glass carriers can be considered. When a glass carrier is used, the substrate on top of it can be debonded or released by laser, thermal-mechanical and/or chemical debonding.

Clad metals can also be pre-processed to create holes, micro-holes and/or cavities. Photoresist etching and electrochemical machining are widely known as precision methods for machining micro-holes with no residual stress and lower surface roughness on the fabricated products. A machining method that combines photoresist etching and electrochemical machining can be applied to etch Invar shadow masks used for organic light-emitting diodes (OLEDs) contain numerous micro-holes. To create circular and deeper micro-holes without blurs and thermal damage in Invar, one can also use either micro-electro-discharge machining or an ultrashort pulsed laser such as a regenerative amplifier Ti:sapphire laser with a 1 kHz repetition rate, a 184 fs pulse duration, and a 785 nm wavelength. An electro-chemical approach which involves contacting the copper within the Cu-Invar-Cu core encapsulated between a pair of dielectric films with a copper etching aqueous solution of a strong base and a strong oxidizing acid (while maintaining the copper anodic) can also be used to create patterns in Cu and micro-holes in Invar. Although Cu and Invar etch differently using wet etching alone, it is possible to adjust the concentrations of FeCl₃ and CuCl₂ to come up with optimum conditions for uniform patterning. Spray etching may also be used in conjunction with wet etching to create more uniform patterns.

Molybdenum masks with tiny holes can also be created by electrochemical etching with patterned masks. In this case, Molybdenum sheet or foil is masked with patterned photoresist on one side, and a mating, mirror-image pattern of photoresist is applied on the other side of the foil in exact registration with the first pattern. The foil is immersed in electrolyte (an aqueous solution of sodium nitrate, sodium hydroxide, thiourea, and surfactant) along with nickel anode plates held parallel to the foil surfaces 1 cm to 3 cm away. The anode plate is made slightly smaller than the mask area of the foil. When voltage is applied across the cell, the foil is etched through to form vias. The electrolyte is pumped across the surface of the foil and uniform flow velocity over the foil surface is achieved. Molybdenum photochemical etching is also common for industries that require a low coefficient of thermal expansion and high elastic moduli such as aerospace, medical, defense, and telecommunications. One type of molybdenum wet etching solution is made up of the following contents: 30 ml H₃PO₄, 18 ml HNO₃, 10 ml CH₃COOH, 65 ml H₂O. To reduce hazardous waste, ferric sulfate and ferric ammonium sulfate can be considered as the etchant. Molybdenum photochemical etching machines are commercially available. Hole sizes as small as 0.006″ or smaller can be created depending of Mo thicknesses. It is worth noting that dry etching of Molybdenum based on SF₆, BCl₃ and Ar gases has been done for high-topography MEMS device fabrication.

In addition to supporting high-end packaging, the ultrafine pitch advanced laminate substrate with or without the thermally controlled core such as Cu-Invar-Cu can also be used to support high-pin-count probe cards for high-end flip chip packaging in support of HPC, data centers and AI (Artificial Intelligence). Pin count and laminate substrate size for high-end packaging are fast increasing which impose challenges on probing of flip chip bumped wafers, whether they involve solder bumps or copper pillar micro-bumps, and on the wiring densities of the proportionally smaller laminate portions (caused by the expanding large area arrays on larger chips) of fine-pitch vertical probe cards. As in the case of advanced packaging, high-layer-count, ultra-fine pitch laminate substrate can find utilities here.

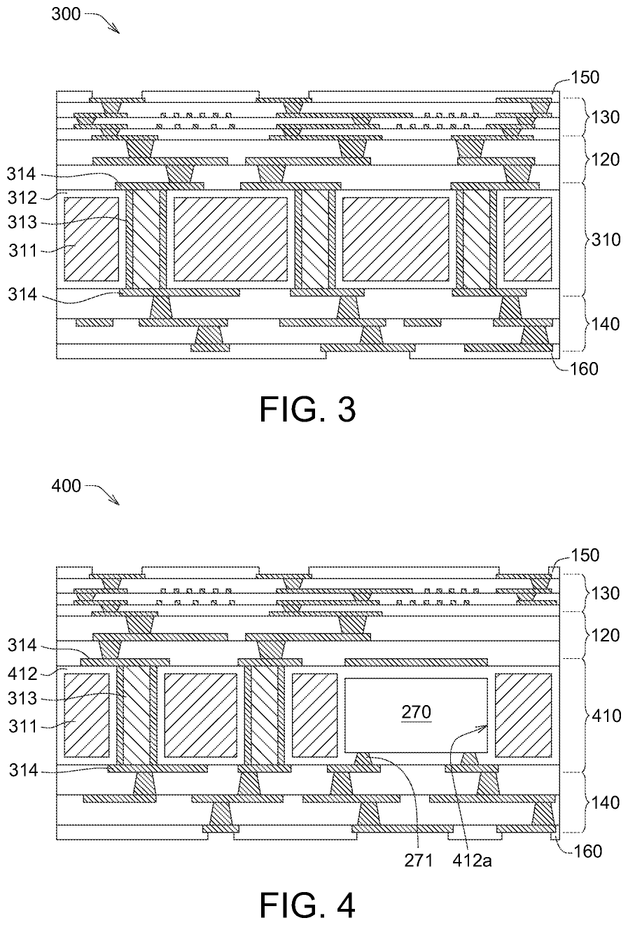

Referring to FIG. 3, FIG. 3 is a schematic diagram of a semiconductor device 300 according to an embodiment of the present disclosure. The semiconductor device 300 includes a core 310, the first build-up structure 120, the input/output conductive structure 130, the second build-up structure 140, the first solder mask 150 and the second solder mask 160.

As shown in FIG. 3, the semiconductor device 300 includes the features similar to or the same as that of the semiconductor device 100, and at least one difference is that the core 310 of the semiconductor device 300 and the core 110 are different in structure. For example, the core 310 is a clad metal structure. The core 310 includes a plurality of clad metal blocks 311, an insulation layer 312, a plurality of conductive vias 313 and a plurality of conductive portions 314. The conductive vias 313 pass through the insulation layer 312 and electrically connecting the conductive portions 314. The clad metal blocks 311 can conduct the heat to outside of the semiconductor device 300. The clad metal block which can be formed of a material such as Cu-Invar-Cu or Cu—Mo—Cu allows one to tailor its thermal properties by adjusting the individual layer thicknesses. The conductive portions 314 are formed on two opposite sides of the insulation layer 312. The clad metal block 311 has a low-CTE and a high-thermal-conductivity.

Referring to FIG. 4, FIG. 4 is a schematic diagram of a semiconductor device 400 according to an embodiment of the present disclosure. The semiconductor device 400 includes a core 410, the first build-up structure 120, the input/output conductive structure 130, the second build-up structure 140, the first solder mask 150, the second solder mask 160 and at least one electronic component 270.

The semiconductor device 400 includes the features similar to or the same as that of the semiconductor device 300, and at least one difference between them is that the semiconductor device 400 further includes the electronic component 270 which is embedded in the core 410, and the core 410 of the semiconductor device 400 and the core 310 are different in structure.

As shown in FIG. 4, in an embodiment, the electronic component 270 is, for example, an active component or a passive component. For example, the electronic component 270 is a grounded and Faraday shielded IVR, a voltage regulator component (for example, the first voltage regulator component), a voltage regulating circuit, or a sub-circuitry. In another example, the electronic component is a silicon interconnect substrate which can be a passive component or an active component. The electronic component 270 includes at least one conductive contact 271 which is electrically connected to the second build-up structure 140, and electrically connected to the input/output conductive structure 130 through the core 410 and the first build-up structure 120.

As shown in FIG. 4, the core 410 includes a plurality of clad metal blocks 311, an insulation layer 412, a plurality of conductive vias 313 and a plurality of conductive portions 314. The conductive vias 313 pass through the insulation layer 412 and electrically connecting the conductive portions 314. The clad metal blocks 311 can conduct the heat to outside of the semiconductor device 400. The clad metal block which can be formed of a material such as Cu-Invar-Cu or Cu—Mo—Cu allows one to tailor its thermal properties by adjusting the individual layer thicknesses. The conductive portions 314 are formed on two opposite sides of the insulation layer 412. In the present embodiment, the insulation layer 412 has a recess 412a within which the electronic component 270 is disposed.

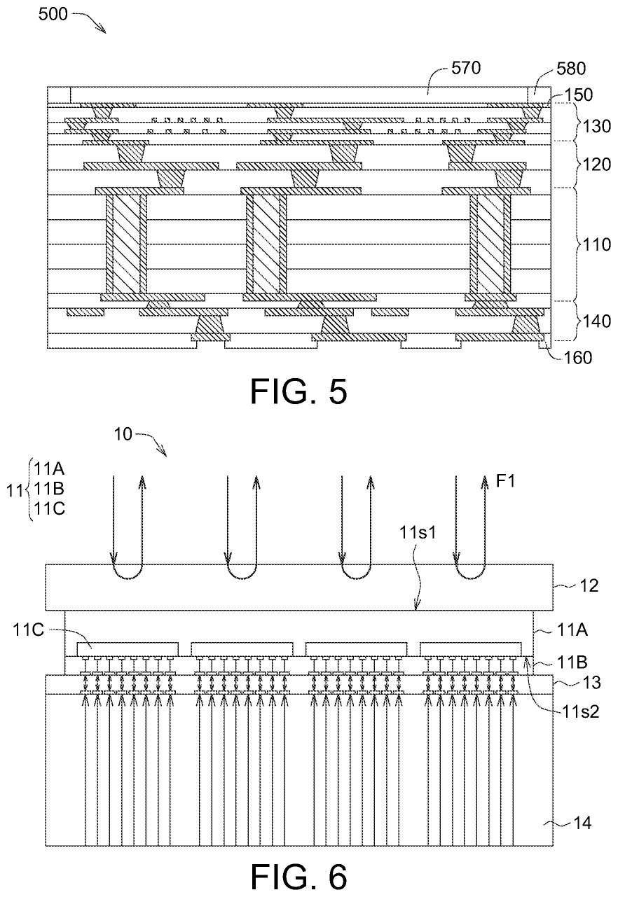

Referring to FIG. 5, FIG. 5 is a schematic diagram of a semiconductor device 500 according to an embodiment of the present disclosure. The semiconductor device 500 includes the core 110, the first build-up structure 120, the input/output conductive structure 130, the second build-up structure 140, the first solder mask 150, the second solder mask 160, at least one electronic component 570 and an encapsulation 580.

The semiconductor device 500 includes the features similar to or the same as that of the semiconductor device 100, and at least one difference between them is that the semiconductor device 500 further includes the semiconductor component 570 which can be a passive silicon interconnect with bonding pads on both its top and bottom sides, or an active component and the encapsulation 580.

As shown in FIG. 5, the electronic component 570 is disposed over and electrically connected to the input/output conductive structure 130. The encapsulation 580 covers at least one portion of the electronic component 570. The electronic component 570 is, for example, an active component or a passive component. In another embodiment, as in the case of the semiconductor device 500, the aforementioned semiconductor device (100, 200, 300 or 400) can include further the electronic component 570 and the encapsulation 580 disposed on the input/output conductive structure 130 of the aforementioned semiconductor device.

Referring to FIG. 6, FIG. 6 is a schematic diagram of a semiconductor device 10 according to an embodiment of the present disclosure. The semiconductor device 10 includes a semiconductor wafer 11, a cold plate 12, a substrate 13 and a PCB 14.

As shown in FIG. 6, the semiconductor wafer 11 has a first side 11s1 and a second side 11s2 opposite to the first side 11s1 and includes a plurality of circuits 110 formed adjacent to the second side 11s2.

As shown in FIG. 6, the cold plate 12 is disposed on the first side 11s1. The semiconductor wafer 11 further includes a base 11A and a BEOL/RDL 11B (with solder bumps or other types of metal connectors), wherein the BEOL/RDL 11B is formed on the base 11A and electrically connected to the circuits 11C. A water flow F1 can cool the semiconductor wafer 11 through the cold plate 12. The base 11A is, for example, silicon substrate.

As shown in FIG. 6, the ultrafine L/S/pitch substrate 13 includes the features similar to or the same as that of the aforementioned semiconductor device, for example, one of the semiconductor devices 100, 200, 300, 400 and 500. In an embodiment, the substrate 13 can be replaced by one of the semiconductor devices 100, 200, 300, 400 and 500. The substrate 13 is disposed on the second side 11s2 of the semiconductor wafer 11 and is electrically connected to the circuits 11C on the second side 11s2 of the semiconductor wafer 11 through the input/output conductive structure 130 (not shown in FIG. 6) of the substrate 13 and to the PCB 14 through the second build-up structure 140 (not shown in FIG. 6) of the substrate 13.

The ultrafine L/S/pitch substrate as shown in FIG. 6 can be used as the ultra-high-density advanced laminate substrate for ultra-high-end AI applications. A case in point is the interconnection scheme of Cerebras's wafer-level (8″×8″) wafer-scale SoC.

Recently, there evolves a trend for massively parallel AI high-performance computing which handles massively parallel workloads such as graph processing, data analytics and machine learning. The proliferation of these AI systems is driving massively parallel, high-performance computing systems with an ever-larger number of processor cores, ever-more extensive memory capacity, as well as ever-higher-bandwidth memory. To create such systems, there exists one approach by Cerebras that creates a monolithic wafer-scale single-die AI processor SoC chip (about 8″×8″ in size). Cerebras's wafer-scale engine can contain 2.6 trillion transistors and 850,000 cores on a 46,225 mm² silicon footprint. Compared to Nvidia's A100, the largest GPU available (826 mm²), Cerebras achieves many advantages, notably 40 GB of memory bandwidth versus 40 MB for A100. The Cerebras approach creates the largest SoC the industry has ever seen. A single Cerebras wafer-scale engine (WSE) uses 20 kilowatts of power. For comparison, an Nvidia A100 ranges from 250 W to 500 W depending on the configuration, and according to a recent survey by AFCOM (Advanced Data Centers and IT Infrastructure Professionals), users were averaging 7.3 kilowatts of power for an entire rack in data centers, which holds as many as 40 servers. It was reported that the WSE will be packaged as a server appliance, which will include a liquid cooling system that reportedly incorporates a cold plate fed by a series of pipes, with the wafer-scale chip positioned vertically in the chassis to cool the entire chip surface in a sandwich arrangement as shown in FIG. 6.

Ultrafine L/S/pitch advanced laminate substrates with particularly the semiconductor device 300 and the semiconductor device 400 disclosed herein can be used for wafer-scale SoC applications to absorb the thermal displacement under changes in temperature without breaking any electrical connections between the large wafer-scale SoC and the substrate. This invention discloses the use of a laminate substrate (for example, the semiconductor device 300 or the semiconductor device 400) containing a clad metal such as copper-invar-copper or copper-Mo-copper to make the connector as shown in FIG. 6, taking advantage of the thermal expansion matching that can be engineered or tailored between the clad metal embedded substrate, silicon and PCB, and high thermal conductivities of clad metals. The clad metal substrate can also contain redistribution and build-up layers that connect to the wafer-scale chip on the top side and the PCB on the bottom side with through vias. To provide better control of the overall expansion of the substrate and its thermal conductivity when needed, the clad metal layer can also be incorporated on both the top side and the bottom side of the substrate 13 in FIG. 6.

Referring to FIG. 7, FIG. 7 is a schematic diagram of a semiconductor device 20 according to an embodiment of the present disclosure. The semiconductor device 20 includes an ultrafine L/S/pitch, low-CTE, high-thermal-conductivity substrate 13 (e.g., the semiconductor device 300 or the semiconductor device 400), a heatsink 21, a silicon interconnect component 22 supporting multiple chips or chiplets, a hat (high-thermal-conductivity heat spreader) 23, a first low-stress thermal conductor layer 24, a second low-stress thermal conductor layer 25 and a cold plate 26. The silicon interconnect component 22 with chips or chiplets mounted is disposed between the first low-stress thermal conductor layer 24 and the input/output conductive structure 130 (not shown in FIG. 7) of the substrate 13 for chiplet interconnection, and electrically connected to the input/output conductive structure 130 of the substrate 13. The hat 23 is disposed between the heatsink 21 and the first low-stress thermal conductor layer 24. In another embodiment, the second low-stress conductor layer 25 includes the features similar to or the same as those of the aforementioned semiconductor device, for example, one of the semiconductor devices 100, 200, 300, 400 and 500. In this case, the second low-stress conductor layer 25 can replace the PCB for certain applications.

The Cerebras's approach for massively parallel AI computing creates the largest SoC the industry has ever seen. There exists a parallel AI approach which creates the largest SiP the industry has ever witnessed and which can use the cooling scheme shown in FIG. 7. This approach is championed by researchers from University of California, Los Angeles and the University of Illinois, Urbana-Champaign (the UC-UI approach). This is a chiplets-in-SiP packaging approach which manifests itself in the 1024-tile (with each tile containing one logic chiplet and one memory chiplet), 14,336-core package based on a wafer-scale silicon interconnect substrate (15,000 mm², or equivalently 4.8″×4.8″). In this approach, power is delivered from the edge, and the silicon substrate is fabricated via step-and-repeat patterning with the entire wafer divided into smaller identical reticles (7×12 tiles, or 168 chiplets each) and with the inter-chiplet links achieved by 2 μm/3+ μm lines/spaces. The silicon technology uses fine-pitch copper pillar (10 μm pitch) based I/Os, and 100 μm inter-chiplet spacing. A number of I/Os from each of the tiles at the edge of the mesh needs to be fanned out to the edge of the wafer and connected to the external connectors. Each tile consists of a compute chiplet and a memory chiplet. Each 40 nm compute chiplet contains 14 independently programmable ARM Cortex-M3 processor cores with 64 k bits of local SRAM while the memory chiplet provides 512 KB of globally shared memory. The system is architected as a unified memory system where any core on any tile can directly access the globally shared memory across the entire wafers-scale system using the interconnect. The wafer-scale silicon interconnect substrate is a passive substrate containing the interconnect wiring between the chiplets and “copper pillars” to connect to the chiplet I/Os. This large 4.8″×4.8″ substrate can be replaced by the large, high-layer-count, ultrafine L/S/pitch laminate substrates with the clad metal cores, which also find utilities in the cooling of such large SiP.

When it comes to high-chip-count SiPs, IBM utilized thermal conduction module (TCM) to achieve thermal management for high-performance computers such as mainframes containing 100+ chips. This cooling system used spring loaded metal elliptical shaped pistons attached to the cooling hat to conduct the heat away from the backside of the flip chip bonded chip and the elliptical piston shape allowed the piston to be deflected from the hot spot on the backside the chip through the spring making sure a cooler portion of the piston is always in contact with the hot spot of chip. This system can be extended from air or water cooling to liquid nitrogen cooling or cooling by other types of cryogenic fluids (e.g., helium).

Because the number of chiplets in the UC-UI approach is huge (2,048 tiny chiplets, way beyond IBM's TCM which involved 100+ much larger chips), this invention discloses replacing the hat/piston/chip system sub-assembly (piston is not scalable to handling an ultra-high number of tiny chiplets; non-immersion cooling (see FIG. 7). This new structure (FIG. 7) involves sandwiching the chiplets mounted silicon interconnect AI system (the silicon interconnect component 22) joined to an ultrafine L/S laminate substrate (UFL; substrate 13) between two thermal expansion matching (to that of silicon), low-stress thermal conductor layers 24 and 25 (e.g., Cu-invar-Cu or Cu—Mo—Cu with high-thermal-conductivity thermal interface materials) with the top low-stress thermal conductor layer 24 attached to the hat 23 and the bottom low-stress thermal conductor layer 25 to the cold plate 26. The silicon interconnect component 22 can be a large silicon interposer with through silicon vias and redistribution layers on both the top side (chip side) and the bottom side of the substrate. It can also be a clad metal substrate with redistribution layers and even build-up layers. The silicon interconnect component 22 can contain power vias and thermal vias, and it can be connected to the substrate 13 through, for instance, solder bumps/balls. The top low-stress thermal conductor layer 24 can be connected through a thermal interface material, a solder, sintered Ag or a high thermal conductivity semi-sintered material to the backside of chiplets. The bottom low-stress thermal conductor layer 25 can be connected through a thermal interface material, a solder, sintered Ag or a high thermal conductivity semi-sintered material to the cold plate 26. The substrate, in turn, can contain embedded conductive metal layers, an embedded clad metals, and/or thermal vias to facilitate heat dissipation.

One variation of the structure proposed in FIG. 7 has to do with sandwiching the silicon interconnect AI system 22 between the top thermal conductor layer 24 and the bottom thermal conductor layer 25 without the substrate 13. In this case, the structure of the bottom thermal conductor layer 25 can mimic that of the substrate 13 and can assume the structure of semiconductor device 300 or 400 containing thermal vias/planes as needed for enhanced heat dissipation. In extreme cases, one can extend the embodiments above to include dunking the conductor—AI system on the UFL—conductor sub-assembly directly in a thermal transfer fluid (such as a dielectric coolant, for example, a fluorocarbon coolant or a hydrocarbon coolant, liquid nitrogen or other cryogenic fluids) using a liquid immersion system with or without forced convection.

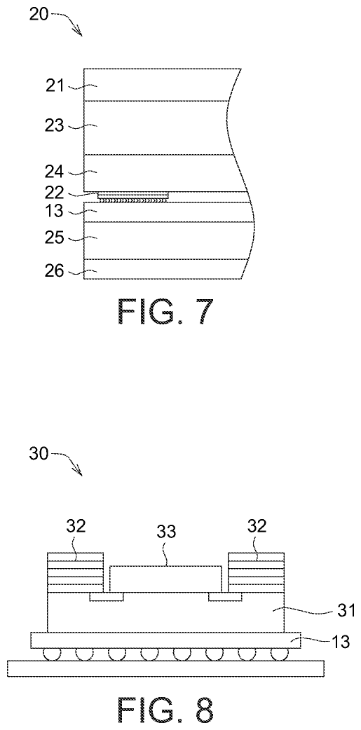

Referring to FIG. 8, FIG. 8 is a schematic diagram of a semiconductor device 30 according to an embodiment of the present disclosure. The semiconductor device 30 includes the substrate 13, an interposer 31, at least one memory component 32 and a processor 33. The interposer 31 is disposed on the input/output conductive structure 130 (not shown in FIG. 8) of the substrate 13. The memory components 32 are disposed on the interposer 31. The processor 33 is disposed on the interposer 31. The memory components 32 and the processor 31 are disposed side-by-side. In an embodiment, the memory component 32 is, for example, a High Bandwidth Memory (HBM).

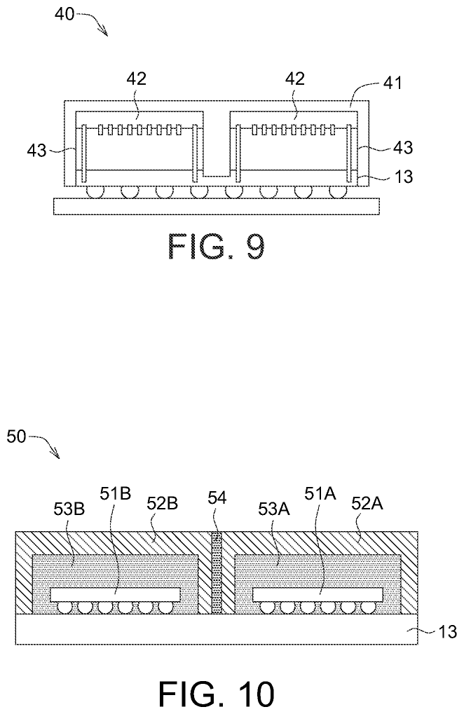

Referring to FIG. 9, FIG. 9 is a schematic diagram of a semiconductor device 40 according to an embodiment of the present disclosure. The semiconductor device 40 includes the substrate 13, an encapsulation 41, at least one memory component 42 and at least one processor 43. The processors 43 are disposed on the input/output conductive structure 130 of the substrate 13. Each memory component 42 is disposed on top of the corresponding processor 43. The encapsulation 41 encapsulates the substrate 13, the memory components 42 and the processors 43. In an embodiment, the memory components 42 is, for example, a HBM.

For 2D IC, 2.5D or 3D IC packaging, supplying voltage to the second tier of an IC stack presents challenges using flip chip and through silicon vias (which increases resistance, resulting in voltage drop and decreased performance). One can distribute the IVR network on substrate, in-substrate and/or in active dies (including active portions of IVR on the first die bonded to the substrate) to minimize the impact for 2.5D and 3D ICs in support of near-memory and in-memory computing as shown in FIGS. 8 and 9 while minimizing EMI impact.

Referring to FIG. 10, FIG. 10 is a schematic diagram of a semiconductor device 50 according to another embodiment of the present disclosure.

As shown in FIG. 10, the semiconductor device 50 includes the substrate 13, at least one first electronic component 51A, at least one second electronic component 51B, a first conformal metal component 52A, a second conformal metal component 52B, a first encapsulation body 53A, a second encapsulation body 53B and a metal 54.

As shown in FIG. 10, the first electronic component 51A and the second electronic component 51B are disposed on the substrate 13 side by side. In an embodiment, the first electronic component 51A and/or the second electronic component 51B can be, for example, a grounded Faraday shielded IVR, a voltage regulator component, a voltage regulating circuit, or a sub-circuitry and/or a passive component. In another embodiment, the first electronic component 51A and/or the second electronic component 51B can be, for example, an IVR.

As shown in FIG. 10, the first encapsulation body 53A is formed on the substrate 13 and encapsulates the first electronic component 51A, and the first conformal metal component 52A covers or surrounds the first encapsulation body 53A. Similarly, the second encapsulation body 53B is formed on the substrate 13 and encapsulates the second electronic component 51B, and the second conformal metal component 52B covers or surrounds the second encapsulation body 53B. The first conformal metal component 52A and the second conformal metal component 52B can be grounded through a grounded trace or a grounded layer (not shown).

The IC mounted on the substrate embodying voltage regulated grounded Faraday shield can also be Faraday shielded from other ICs in the same package by forming conformal and/or compartment shielding layers/structures on/in the molding compound which are connected to for example, a ground plane in the substrate. Besides forming the Faraday shields using substrate processes, this package can be conformal shielded by sputtering a thin composite layer (a few micrometers) of, for instance, stainless steel/copper/stainless steel, over the molding compound (with, for instance, the conformal layer connected to the ground layer in the substrate) which is connected to a ground plane in the substrate. When more than one die is involved, the main RF or noisy chip can also be isolated from the other dies, and shielded individually through both conformal shielding and compartment shielding using, for example, metal particles filling compartment vias (see 54 in FIG. 10) and sidewalls.

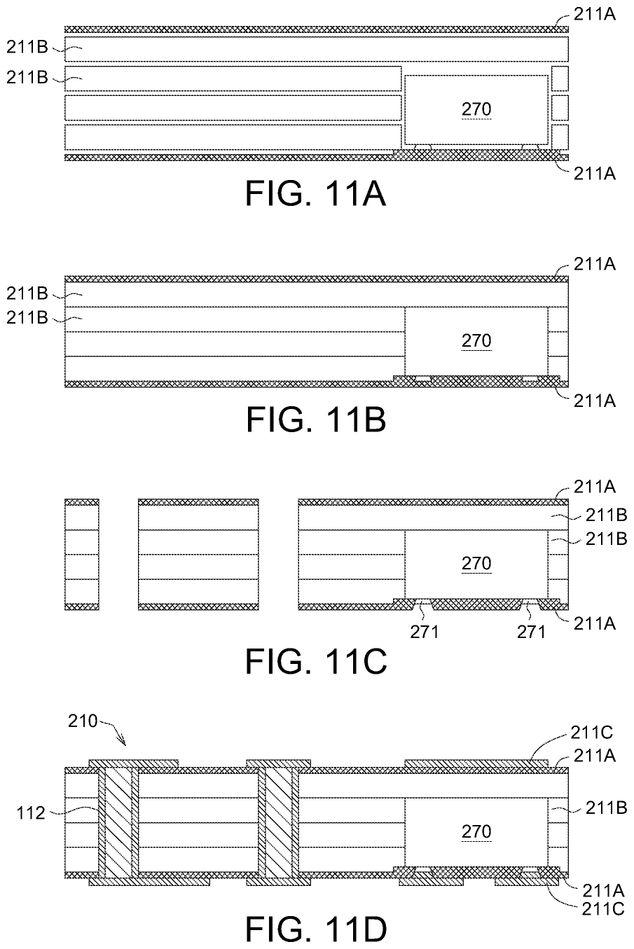

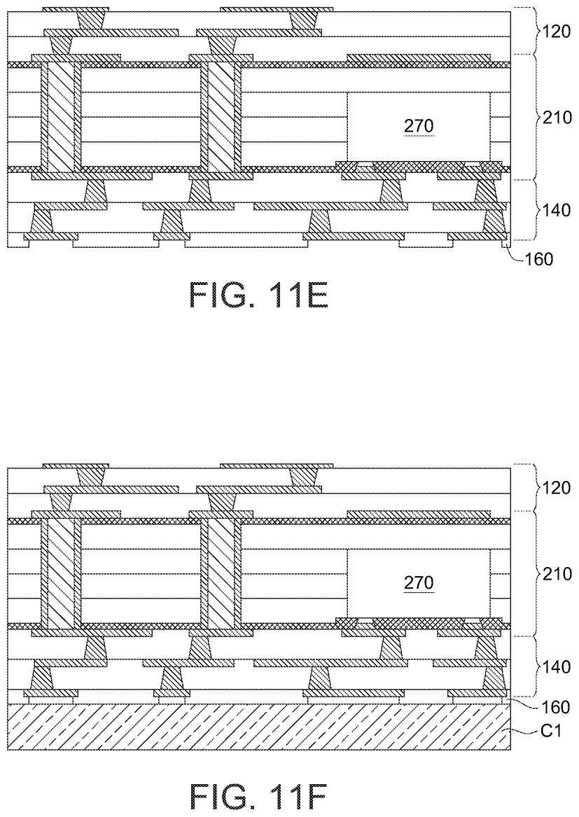

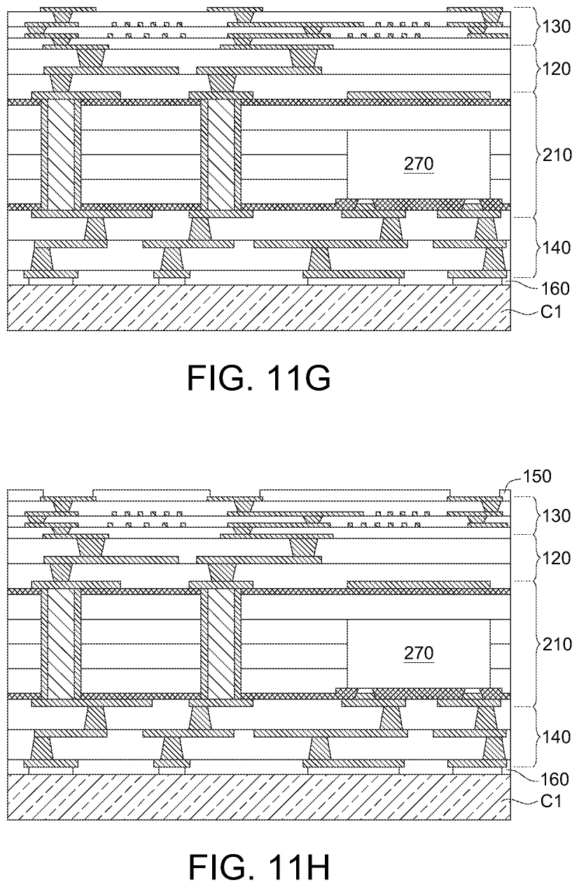

Referring to FIGS. 11A to 11H, FIGS. 11A to 11H are schematic diagrams of manufacturing processes of the semiconductor device 200 of FIG. 2 according to another embodiment of the present disclosure.

As shown in FIGS. 11A and 11B, a plurality of the first dielectric layers 211A and a plurality of the second dielectric layers 211B are provided, wherein the dielectric used in the first dielectric layer 211A preferably is identical or similar to the dielectric used in the second dielectric layer 211B. The first dielectric layer 211A can be formed by laser marking of fiducials and deposition (e.g., by printing) of an adhesion layer (again identical to or similar to the dielectric used in the second dielectric layer 211B) on the base dielectric layer. Subsequently, the electronic component 270 is attached to the adhesion layer in the first dielectric layer 211A. A plurality of the second dielectric layers 211B are pre-punched to create a recess to subsequently enclose the electronic component 270. Following this, a plurality of the second dielectric layers 211B (with some layers pre-punched) are stacked on top of the electronic component 270 mounted on the lower first dielectric layer 211A as shown in FIG. 11A with the upper first dielectric layer 211A (similar to the one for bonding of the electronic component 270 but without the printed adhesion layer) as needed on top of the second dielectric layers 211B to enclose the electronic component 270. Following this, hot press lamination ensues to form the structure shown in FIG. 11B under the application of pressure and heat which melts the dielectric in the first dielectric layer 211A and the second dielectric layer 211B to encapsulate the electronic component 270. In addition, the second dielectric layer 211B may be formed of a material including, BT.

As shown in FIGS. 11C and 11D, at least one conductive via 112 passing through the first dielectric layer 211A and the second dielectric layer 211B is created, a plurality of contacts 271 of the electronic component 270 are exposed and a plurality of conductive portion 211C are formed on two opposite sides of the first dielectric layers 211A to form the core 210 (see FIG. 11D) by, for instance, laser drilling (or mechanical drilling as warranted) to create the through via opening (see FIG. 11C), desmear, thin Cu deposition, photoresist deposition and patterning, Cu plating/hole fill, photoresist removal, thin Cu etching, etc. The conductive portion 211C can be electrically connected to the conductive via 112 and/or the electronic component 270. So far, the core 210 within which the electronic component 270 is disposed is formed.

As shown in FIG. 11E, the first build-up structure 120 is formed on an upper surface of the core 210 by, for instance, dielectric (e.g., ABF) deposition, laser via formation and desmear, thin Cu deposition, photoresist deposition and patterning, Cu plating, photoresist removal, thin Cu etching, etc., the second build-up structure 140 is formed on a lower surface of the core 210, and the second solder mask 160 is formed on the second build-up structure 140.

As shown in FIG. 11F, the structure of FIG. 11E is disposed on a temporary carrier C1 (which serves as a mechanical support to minimize effects due to substrate warpage, etc.) with the use of a release layer as the adhesive. The temporary carrier here can be a glass carrier. The release layer can be a polymer-based release/adhesive layer (not shown in FIG. 11F) that allows release of the substrate structure by laser irradiation, thermos-mechanical/chemical, etc. approaches following substrate processing.

As shown in FIG. 11G, the input/output conductive structure 130 is formed on the first build-up structure 120 by, for instance, dielectric deposition and patterning, seed layer deposition, conductor trace definition, Cu plating, photoresist removal, metal etching, etc.

As shown in FIG. 11H, the first solder mask 150 is formed on the input/output conductive structure 130.

Then, the temporary carrier C1 can be removed to expose the second build-up structure 140 and the second solder mask 160. So far, the semiconductor device 200 is formed.

The manufacturing method of the semiconductor device 100 includes the processes similar to or the same as that of the semiconductor device 200.

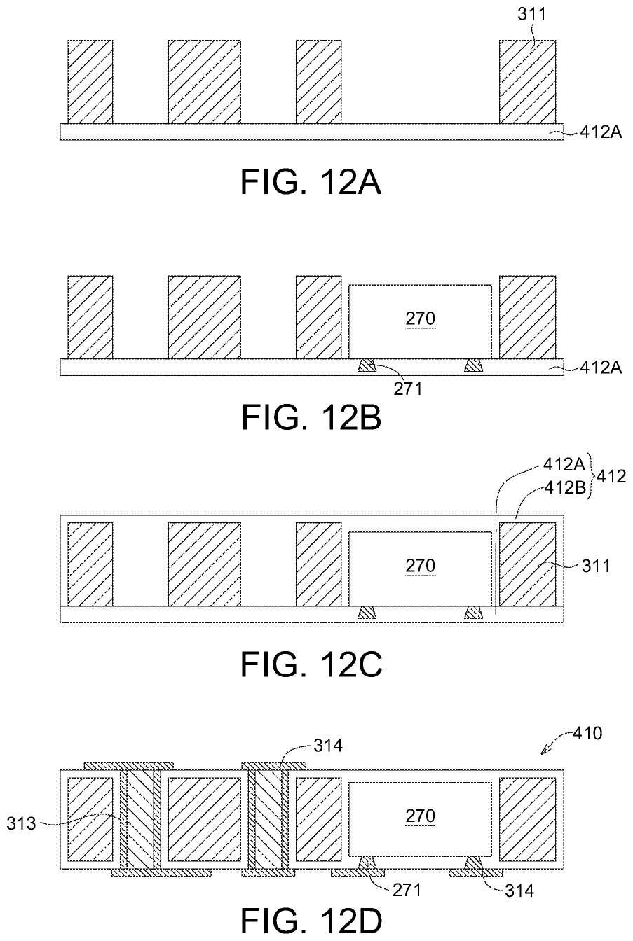

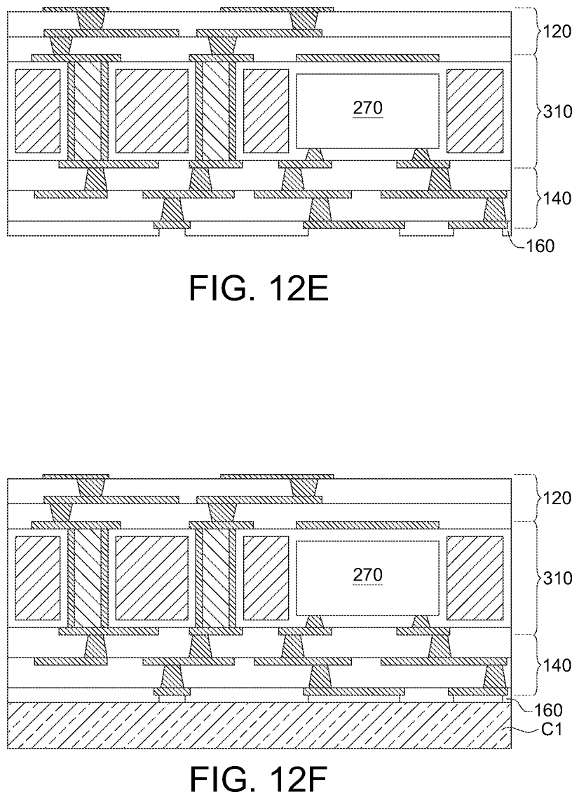

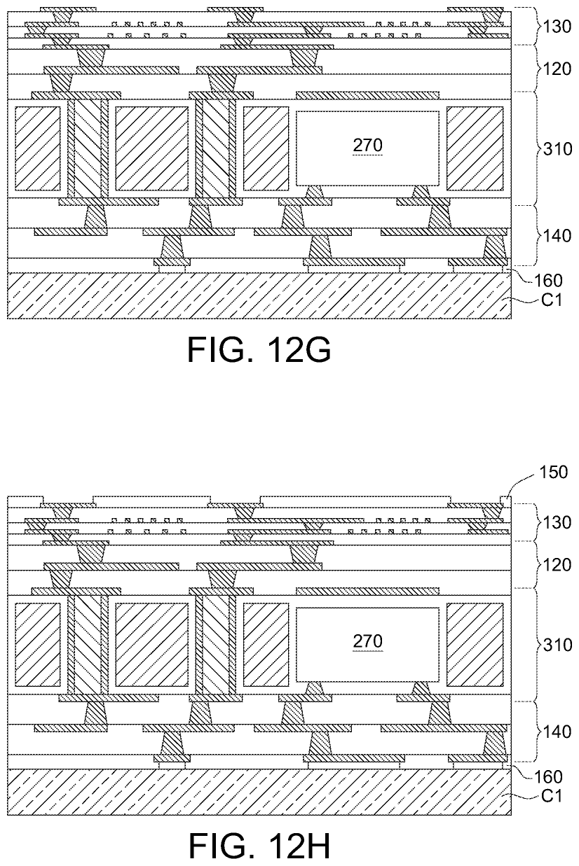

Referring to FIGS. 12A to 12H, FIGS. 12A to 12H are schematic diagrams of manufacturing processes of the semiconductor device 400 of FIG. 4 according to another embodiment of the present disclosure.

As shown in FIG. 12A, a plurality of the clad metal blocks 311 are disposed on an insulation layer 412A In an embodiment, the clad metal blocks 311 can be connected as a single clad metal piece having a cavity for the embedded component.

As shown in FIG. 12B, the electronic component 270 is disposed within a hole or a cavity of the clad metal blocks 311.

As shown in FIG. 12C, an insulation layer 412B is stacked on the insulation layer 412A and cover the electronic component 270 and the clad metal blocks 311. The insulation layer 412B and the insulation layer 412A form the insulation layer 412.

As shown in FIG. 12D, at least one conductive via 313 passing through the insulation layer 412 is created, a plurality of contacts 271 of the electronic component 270 are exposed and a plurality of conductive portion 314 are formed on two opposite sides of the insulation layer 412 to form the core 410 (see FIG. 12D) by, for instance, laser drilling (or mechanical drilling as warranted) to create the through via opening, desmear, thin Cu deposition, photoresist deposition and patterning, Cu plating/hole fill, photoresist removal, thin Cu etching, etc. The conductive portion 314 can be electrically connected to the conductive via 313 and/or the electronic component 270.

As shown in FIG. 12E, the first build-up structure 120 is formed on an upper surface of the core 410, the second build-up structure 140 is formed on a lower surface of the core 410, and the second solder mask 160 is formed on the second build-up structure 140.

As shown in FIG. 12F, the structure of FIG. 12E is disposed on a temporary carrier C1 (which serves as a mechanical support to minimize effects due to substrate warpage, etc.) with the use of a release layer as the adhesive. The temporary carrier here can be a glass carrier. The release layer can be a polymer-based release/adhesive layer (not shown in FIG. 12F) that allows release of the substrate structure by laser irradiation, thermos-mechanical/chemical, etc. approaches following substrate processing.

As shown in FIG. 12G, the input/output conductive structure 130 is formed on the first build-up structure 120.

As shown in FIG. 12H, the first solder mask 150 is formed on the input/output conductive structure 130.

Then, the temporary carrier C1 can be removed to expose the second build-up structure 140 and the second solder mask 160. So far, the semiconductor device 400 is formed.

The manufacturing method of the semiconductor device 300 includes the processes similar to or the same as that of the semiconductor device 400.

The manufacturing method of the semiconductor device 50 in FIG. 10 includes the following steps. First, the first electronic component 51A and the second electronic component 51B are disposed on the input/output conductive structure 130 of the substrate 13. Then, the first encapsulation body 53A and the second encapsulation body 53B are disposed on the input/output conductive structure 130 of the substrate 13, wherein the first encapsulation body 53A encloses the first electronic component 51A, and the second encapsulation body 53B encloses the second electronic component 51B. Then, the first conformal metal component 52A over the first encapsulation body 53A which are electrically connected to the ground planes of the substrate 13 and the second conformal metal component 52B over the second encapsulation body 53B which are electrically connected to the ground planes of the substrate 13 are formed.

In addition to using organic laminate substrate as the basis, other substrates can also be considered. They include but no limited to silicon (passive and active with active functions such as active die functions or part of them), glass, and glass ceramic, and molding compound with redistribution layers for die embedding (as in lead frame, fan-out, package-on-package, package-in-package and other single-die and SiP packages). Processes are available to handle these substrates for embedding and creation of conformal and compartment shielding, whether they be related to through via creation, formation of metal and redistribution layers and/or conformal and compartment shielding. In case when silicon is used as the substrate, it can be micro-machined as in the case of silicon interposer and MEMS processing to create a cavity with through vias to encase and shield the IVR or part of it within. This applies to silicon interposers and active dies.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A semiconductor device, comprising:
a core having a first surface and a second surface;
a first build-up structure formed on the first surface and/or the second surface and comprising a plurality of first build-up conductive portions; and
an input/output conductive structure formed above the first build-up structure and comprising a plurality of input/output conductive portions;
wherein an input/output line width/line spacing (L/S) of the input/output conductive portions is different from a first L/S of the first build-up conductive portions.

2. The semiconductor device claimed in claim 1, wherein the first build-up structure is formed on the first surface of the core, and the semiconductor device further comprises:
a second build-up structure is formed on the second surface of the core and comprising a plurality of second build-up conductive portions;
wherein the input/output L/S or a second L/S of the second build-up conductive portions is different from the first L/S of the first build-up conductive portions.

3. The semiconductor device claimed in claim 1, wherein the input/output L/S of the first input/output conductive portions is smaller than the first L/S of the first build-up conductive portions.

4. The semiconductor device claimed in claim 1, wherein the input/output conductive structure is a wafer-level or a panel-level fanout RDL (redistribution layers) structure or a wafer BEOL (back-end-of-line) structure.

5. The semiconductor device claimed in claim 1, wherein the first build-up structure is located between the core and the input/output conductive structure.

6. The semiconductor device claimed in claim 1, wherein the core comprises:
a plurality of dielectric layers stacked on each other; and
a plurality of conductive vias passing through the dielectric layers and electrically connecting the first build-up structure and the second build-up structure.

7. The semiconductor device claimed in claim 1, wherein the core comprises:
a plurality of clad metal blocks or a clad metal plate with openings or cavities;
an insulation layer enclosing the clad metal blocks; and
a plurality of conductive vias passing through the insulation layer and electrically connecting the first build-up structure and the second build-up structure.

8. The semiconductor device claimed in claim 1, further comprising:
a semiconductor component disposed over and electrically connected to the input/output conductive structure which is grounded and Faraday shielded.

9. The semiconductor device claimed in claim 1, wherein the minimal input/output L/S of the input/output conductive portions ranges between 1 micrometers (μm) and 5 μm.

10. The semiconductor device claimed in claim 1, further comprising:
a semiconductor wafer having a first side and a second side opposite to the first side and comprising a plurality of circuits formed on the second side; and
a cold plate disposed on the first side;
wherein the core, the input/output conductive structure, the first build-up structure and the second build-up structure form a substrate for interconnection; and the substrate is disposed on the second side of the semiconductor wafer and is electrically connected to the circuits on the second side of the semiconductor wafer through the input/output conductive structure, and to a printed circuit board through the second build-up structure.

11. The semiconductor device claimed in claim 1, further comprising:
a heatsink;
a high-thermal-conductivity heat spreader with or without pistons housed in the heat spreader under the heatsink; and
a silicon interconnect component supporting chips or chiplets disposed between a first low-stress thermal conductor layer with a high-thermal conductivity material or a thermal interface material on both sides of the first low-stress thermal conductor under the heat spreader and the input/output conductive structure and being electrically connected to the input/output conductive structure;
wherein the entire semiconductor device is cooled via air cooling, direct-to-chip liquid cooling or liquid immersion cooling.

12. The semiconductor device claimed in claim 1, further comprising:
an interposer disposed on the input/output conductive structure;
at least one memory component disposed on the interposer; and
a processor disposed on the interposer;
wherein the at least one memory component and the processor are disposed side-by-side.

13. The semiconductor device claimed in claim 1, further comprising:
an interposer disposed on the input/output conductive structure;
at least one processor disposed on the input/output conductive structure or the interposer; and
a memory component mounted on top of each processor.

14. The semiconductor device claimed in claim 1, further comprising:
an electronic component disposed on the input/output conductive structure for interconnection;
an encapsulation body formed on the input/output conductive structure and enclosing the electronic component; and
a conformal metal component and a compartment shield component over the encapsulation body, being electrically connected to a plurality of ground planes.

15. The semiconductor device claimed in claim 1, further comprising:
a semiconductor chip embedded in in the core.

16. A manufacturing method for a semiconductor device, comprising:
forming a core, wherein the core has a first surface and a second surface;
forming a first build-up structure formed on the first surface and/or the second surface, wherein the first build-up structure comprises a plurality of first build-up conductive portions; and
forming an input/output conductive structure above the first build-up structure, wherein the input/output conductive structure comprises a plurality of input/output conductive portions;
wherein an input/output L/S of the input/out conductive structure is different from a first L/S of the first build-up conductive portions.

17. The manufacturing method claimed in claim 16, wherein the first build-up structure is formed on the first surface of the core, and the manufacturing method further comprises:
forming a second build-up structure on the second surface of the core, wherein the second build-up structure comprises a plurality of second build-up conductive portions;
wherein the input/output L/S is different from a second L/S of the second build-up conductive portions.

18. The manufacturing method claimed in claim 16, wherein the input/output L/S is smaller than the first L/S of the first build-up conductive portions, and the minimal input/output L/S ranges between 1 μm and 5 μm.

19. The manufacturing method claimed in claim 16, wherein the input/output conductive structure is formed by a wafer-level or a panel-level fanout RDL process or a wafer BEOL process.

20. The manufacturing method claimed in claim 16, further comprising:
disposing a semiconductor component over and electrically connected to the input/output conductive structure of a substrate.

21. The manufacturing method claimed in claim 16, further comprising:
disposing an electronic component on the input/output conductive structure of the substrate;
forming an encapsulation body on the input/output conductive structure, wherein the encapsulation body encloses the electronic component; and
forming a conformal metal component over the encapsulation body, wherein the conformal metal component is electrically connected to a plurality of ground planes of the substrate.

22. The manufacturing method claimed in claim 16, further comprising:
embedding a semiconductor chip in the core.
